(19) United States
(12) Patent Application Publication
(10) Pub. No.: US 2024/0297011 A1
(43) Pub. Date: Sep. 5, 2024

(54) HOLDING DEVICE ARRANGEMENT FOR USE IN AN IMPLANTATION PROCESS OF A PIEZOELECTRIC SUBSTRATE

(71) Applicant: Soitec, BERNIN (FR)

(72) Inventor: Cédric Charles-Alfred, Grenoble (FR)

(21) Appl. No.: 18/575,538

(22) PCT Filed: Jul. 19, 2022
(86) PCT No.: PCT/EP2022/070201

§ 371 Date: Dec. 29, 2023

(30) Foreign Application Priority Data
Jul. 19, 2021 (FR) FR2107787

(51) Int. Cl. H01J 37/20; H01J 37/317; H10N 30/04

(52) U.S. Cl. CPC H01J 37/20; H01J 37/3171; H10N 30/04

(57) ABSTRACT

A holding device arrangement for use in an implantation process of a piezoelectric substrate comprises a substrate holding device with an elastic and thermo-conductive layer for receiving a piezoelectric substrate, and means for electrically connecting the surface of the elastic and thermo-conductive layer for receiving the piezoelectric substrate to ground potential. A method for implanting a piezoelectric substrate is performed using such holding device arrangement as described above, and an ion implanter may include such a holding device arrangement.

### CROSS REFERENCE TO RELATED APPLICATIONS

This application is a national phase entry under 35 U.S.C. § 371 of International Patent Application PCT/EP2022/070201, filed Jul. 19, 2022, designating the United States of America and published as International Patent Publication WO 2023/001824 Al on Jan. 26, 2023, which claims the benefit under Article 8 of the Patent Cooperation Treaty to French Patent Application Serial No. FR2107787, filed Jul. 19, 2021.

### TECHNICAL FIELD

The present disclosure relates to a holding device arrangement for use in an implantation process of a piezoelectric substrate and to a method of implantation of a piezoelectric substrate using such a holding device arrangement.

### BACKGROUND

The process of ion implantation is used for the fabrication of piezoelectric for fabricating piezoelectric-on-insulator (POI) substrates. In a POI fabrication process, a thin piezoelectric layer is detached from a piezoelectric source substrate at a weakened layer inside the source substrate formed by the implanted atomic species inside the source substrate, and transferred onto a handle substrate.

During implantation, the piezoelectric substrate is mount on a metallic holding device within an implantation chamber and an implantation beam impinges upon a surface of the piezoelectric substrate. To implant atomic species over the entire surface, the substrates are mount on a rotating and/or translating implantation wheel so that the entire surface of the substrate passes under the ion beam. Maintaining means, like clips, are used to fix the substrate on the implanting wheel against the rotational forces. Usually the maintaining means are fixed metallic restraints that are also configured to drain electrical charges generated during the ion implantation.

The implantation of atomic species into the piezoelectric substrate results in an accumulation of charges. At the same time, a high temperature gradient is observed inside the piezoelectric substrate leading to a deformation in the form of bow and warp of the piezoelectric substrate. Consequently, charges and heat cannot be sufficiently dissipated into a metallic holding device.

To remedy this problem, the piezoelectric substrate is placed on an elastomer layer provided over the metallic holding device. This elastomer layer provides a thermal contact between the piezoelectric substrate and the holding device. As mentioned, the fixed metallic restraints are used to provide an electrical contact between the piezoelectric substrate and the holding device. The electrical contact is, however, only a localized contact between the piezoelectric substrate and the holding device and breakage of piezoelectric substrates during implantation is still observed, which is attributed to a still insufficient evacuation of charges.

Therefore, the charge dissipation out of a piezoelectric substrate needs to be further improved.

### BRIEF SUMMARY

The object of the present disclosure is achieved by a holding device arrangement for use in an implantation process of a piezoelectric substrate, comprising a holding device with an elastic and thermo-conductive layer for receiving a piezoelectric substrate, and means for electrically connecting the surface of the elastic and thermo-conductive layer for receiving the piezoelectric substrate to ground potential. Thus, an electrical connection between the piezoelectric substrate and the substrate holding device can be realized. This electrical connection provides an improved evacuation of charges through the elastic and thermo-conductive layer, as evacuation does not only take place via the contact between the metallic restraints and the piezoelectric substrate as in the prior art.

According to a variant of the present disclosure, the elastic and thermo-conductive layer can provide an electrical connection between the substrate holding device and the piezoelectric substrate over more than 30% of the backside surface of the piezoelectric substrate, in particular, more than 50% of the backside surface of the piezoelectric substrate. Thus, a larger contact surface is provided, which improves the electrical connection between the piezoelectric substrate and the substrate holding device.

According to a variant of the present disclosure, the elastic and thermo-conductive layer can comprise a polymer layer, in particular, an elastomer layer. Due to its elasticity, the polymer layer can compensate for deformations of the substrate so that the substrate always remains in thermal contact with the polymer layer and thereby with the substrate holding device. For example, a polymer layer of polydimethyl siloxane with a thermal conductivity of 0.15 W/(m*K) can be used.

According to a variant of the present disclosure, the means for electrically connecting can comprise at least one electrically conductive element embedded in the elastic and thermo-conductive layer, in particular, the polymer layer, to render the elastic and thermo-conductive layer, in particular, the polymer layer, electrically conductive. By embedding the electrically conductive element, the electrical conductivity of the layer can be improved in a simple yet reliable manner.

According to a variant of the present disclosure, the at least one electrically conductive element can be at least one of metallic nano particles or metallic micro particles, carbon-based inclusions, graphite nanoparticles or carbon nanotubes. Those elements can be introduced into the polymer at the moment of fabrication of the elastic and thermos-conductive layer.

According to a variant of the present disclosure, the means for electrically connecting can comprise at least one metallic pin extending through the elastic and thermo-conductive layer to the substrate holding device. It is particularly advantageous to provide a plurality of metallic pins to extend the surface area over which charges can be evacuated.

According to a variant of the present disclosure, each one of the metallic pins can rest on a spring element provided in the substrate holding device. Thus, even under a deformation of the substrate, the pins can remain in contact with the substrate. In addition, the restoring forces of the spring elements ensure a reliable contact.

According to a variant, the metallic pins protrude at least partially beyond the surface of the elastic and thermo-conductive layer when no substrate is present. Thus, an electrical contact can be ensured, even when taking into account fabrication tolerances.

According to a variant of the present disclosure, the means for electrically connecting can comprise a conductive layer, in particular, a metallic layer, provided over the elastic and thermo-conductive layer and extending laterally at least partially over the side surface of the elastic and thermo-conductive layer to be in direct contact with the surface of the substrate holding device. The conductive layer provides a reliable electrical contact with the piezoelectric substrate and the substrate holding device and can be realized using known procedures, e.g., sputtering.

The object of the present disclosure is also achieved by a method of implantation of a piezoelectric substrate, in particular, bulk piezoelectric substrate, using a holding device arrangement as described above, comprising the steps of a) providing a piezoelectric substrate on the holding device arrangement to thereby electrically connect the piezoelectric substrate to ground potential and b) implanting atomic species into the piezoelectric substrate. Using a substrate holding device as described above results in an improved evacuation of charges at the piezoelectric substrate, which results in less breakage of piezoelectric substrates during ion implantation.

The ion implanted piezoelectric substrate can be used as a donor substrate in a subsequent layer transfer process to transfer a thin layer of the piezoelectric material onto a handle substrate, e.g., a silicon wafer, to thereby form a piezoelectric-on-insulator (POI) substrate.

The object of the present disclosure is also achieved with an ion implanter comprising device holding device arrangement as described above.

### BRIEF DESCRIPTION OF THE DRAWINGS

The present disclosure may be understood by reference to the following description taken in conjunction with the accompanying figures, in which reference numerals identify features of the present disclosure.

FIG. 1 schematically illustrates a holding device for use in an implantation process according to a first embodiment of the present disclosure.

FIG. 2A schematically illustrates a holding device for use in an implantation process according to a second embodiment of the present disclosure.

FIG. 2B illustrates a variant of the second embodiment.

FIG. 3 schematically illustrates a holding device for use in an implantation process according to a third embodiment of the present disclosure.

FIG. 4 schematically illustrates a method for implanting a piezoelectric substrate according to a fourth embodiment of the present disclosure.

### DETAILED DESCRIPTION

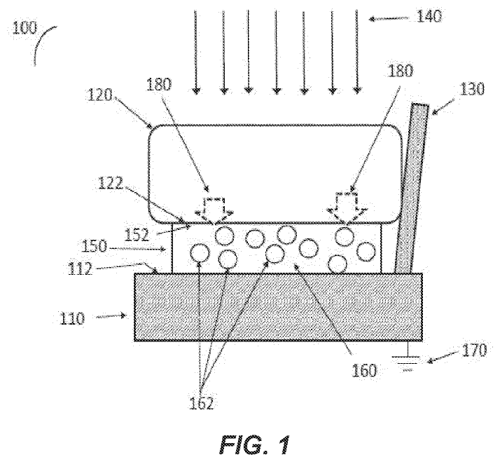

FIG. 1 schematically illustrates a holding device arrangement 100 for use in an ion implanter (not shown) for an implantation process of a piezoelectric substrate according to the first embodiment of the present disclosure.

The holding device arrangement 100 comprises a substrate holding device 110 for holding at least one substrate 120 in a process chamber of an implanter. The substrate holding device 110 is part of or positioned on an implantation wheel of the implanter. The implantation wheel rotates to move the substrates 120 through a beam of ions 140, thereby realizing a homogenous ion implantation into the substrate 120.

The substrate holding device 110 is made of a conductive material, in particular, of metal, for example, of aluminum. The substrate holding device 110 comprises one or more metallic restraints 130 on a lateral side of the substrate holding device 110. In this embodiment, the substrate holding device 110 and the one or more metallic restraints 130 are made of the same conductive material, e.g., the same metallic material, in particular, aluminum. The one or more metallic restraints 130 keeps the substrate 120 in place on the substrate holding device 110, e.g., when the holding device arrangement 100 rotates under a beam of ions 140.

The substrate holding device arrangement 100 further comprises an elastic and thermo-conductive layer 150, which is positioned on surface 112 of the substrate holding device 110. The elastic and thermo-conductive layer 150 comprises a polymer layer 150, in particular, an elastomer layer, to provide an improved thermal contact between the substrate 120 and the substrate holding device 110. The elastic properties of the elastic and thermo-conductive layer 150 compensate for the deformation of the substrate 120 under the stress occurring due to accumulation of charges and the temperature gradient inside the substrate 120 and ensures the thermal contact between the substrate 120 and the substrate holding device 110. The elastic and thermo-conductive layer 150 can be spin coated or deposited on the substrate holding device 110 using various deposition techniques. For example, a polymer layer of polydimethyl siloxane with a thermal conductivity of 0.15 W/(m*K) can be used.

According to the present disclosure, the elastic and thermo-conductive layer 150 further comprises means 160 for electrically connecting the surface 152 of the elastic and thermo-conductive layer 150 that receives the substrate 120, to the substrate holding device 110 underneath which is connected to the ground potential 170.

In this embodiment, the means 160 for electrically connecting comprises at least one electrically conductive element in the form of electrically conductive elements 162 that are embedded in the polymer layer 150 to render the polymer layer electrically conductive. This can be realized by adding metallic nano particles or micro particles or carbon based inclusions, graphite nanoparticles or carbon nanotubes into the polymer layer 150. For example, the particles are mixed inside the liquid polymer matrix. Then, the solution is deposited onto the substrate holding device thanks to a deposition technique such as spin coating. Then, the polymerization of the elastomer is activated by a UV cure and/or thermal treatment. By doing so, the electrical conductivity of the elastic and thermo-conductive layer 150 can be raised from 10 S/cm to on the order of 10+S/cm.

During the implantation process, ions that are implanted into the piezoelectric substrate 120 can generate charges 180, which can be evacuated toward the substrate holding device 110 via the polymer layer 150. The contact surface between the substrate 120 and the polymer layer 150 is larger compared to the contact between the substrate 120 and the fixed restraint 130 in the prior art when electrically isolating polymer layers are used. Thus, the evacuation of charges is improved and less breakage of the piezoelectric substrate occurs during the implantation step.

Indeed, according to the present disclosure the electrical connection can be provided over the entire surface of the polymer layer 150, which represents at least 30%, in particular, at least 50% and more in particular, the entire surface of the backside 122 of the substrate 120, which rests on the polymer layer 150.

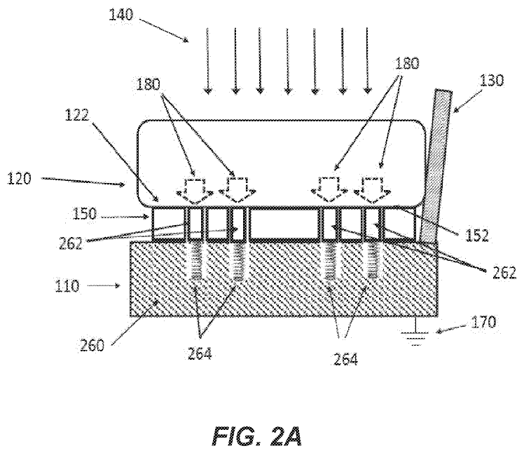

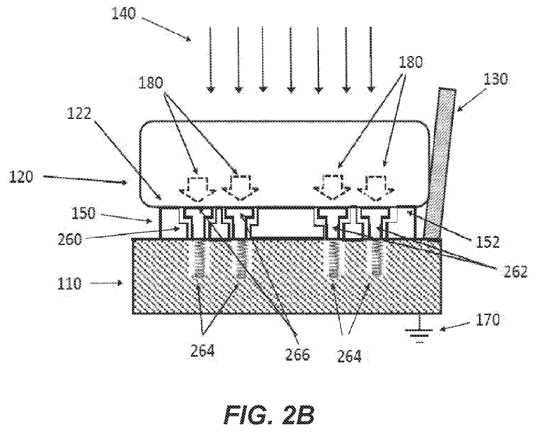

FIGS. 2A and 2B illustrate a holding device arrangement 200 according to a second embodiment of the present disclosure. All features in common with the first embodiment and using the same reference numeral as above will not be described again, but reference is made to their detailed description above.

In the second embodiment shown in FIG. 2A, a plurality of metallic pins 262 are provided in mating through-holes formed in the elastic and thermo-conductive layer 150 instead of embedding particles 162. The metallic pins 262 extend through the elastic and thermo-conductive layer 150 to the substrate holding device 110, which is in contact with the ground potential 170.

In this embodiment, each one of the metallic pins 262 rests on a spring element 264 provided in the substrate holding device 110. The metallic pins 262 and the spring element 264 are designed such that, without a substrate present on the holding device arrangement 200, the metallic pins 262 extend beyond the surface 152 of the elastic and thermo-conductive layer 150. When a substrate 120 rests on the elastic and thermo-conductive layer 150, the spring elements 264 are compressed and the restoring forces of the spring elements push the metallic pins 262 against the backside 122 of the substrate. Thus, an electrical contact with the backside 122 of the substrate 120 is secured and a draining of charges 180 into the substrate holding device is ensured. At the same time, the metallic pins can follow any deformation of the substrate 120 under the ion beam.

According to a variant, as illustrated in FIG. 2B, the pins 262 can comprise an enlarged head portion 266 at the terminal ends of the pins 262 facing the substrate 120, so that the contact area can be even further enlarged.

Thus, like in the first embodiment, an improved evacuation of charges from the substrate 120 can be realized. Charges can also be evacuated via the contact with the fixed metallic restraint 130.

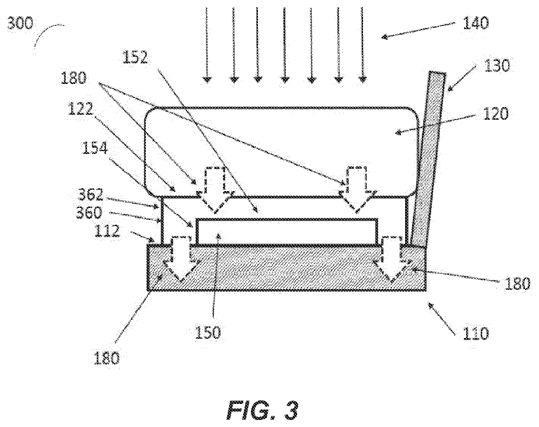

FIG. 3 illustrates a holding device arrangement 300 according to third embodiment of the present disclosure. All features in common with the first embodiment and using the same reference numeral as above will not be described again, but reference is made to their detailed description above.

In the third embodiment, the means for electrically connecting 360 is an electrically conductive layer 362 is provided over the elastic and thermo-conductive layer 150. In this embodiment, the electrically conductive layer 362 is a metallic layer, e.g., an aluminum layer. It is deposited onto the elastic and thermo-conductive layer 150 using deposition techniques known in the art, e.g., sputtering. The thickness of the electrically conductive layer 362 is on the order of 200 μm. The electrically conductive layer 362 is deposited such that it extends at least partially on the lateral edge 154 of the elastic and thermo-conductive layer 150 to extend to the substrate holding device 110. Thus, an electrical contact with the substrate holding device 110 can be realized.

Thus, also in this embodiment a direct electrical contact is provided between the electrically conductive layer 362 and the substrate holding device 110. Therefore, the evacuation of charges 180 from a substrate 120 can take place over a large area on the backside 122 of the substrate 120 into the electrically conductive layer 362 and from there toward the substrate holding device 110 at ground potential 170. Again, charges can also be evacuated via the contact with the fixed metallic restraint 130.

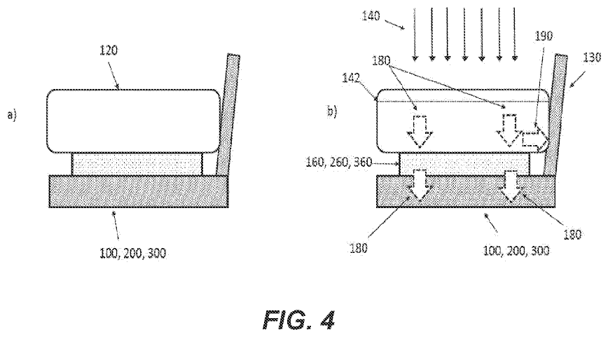

FIG. 4 schematically illustrates a method for implanting a piezoelectric substrate according to a fourth embodiment of the present disclosure. All features in common with the first embodiment and using the same reference numeral as above will not be described again, but reference is made to their detailed description above.

The method for implanting a piezoelectric substrate uses a piezoelectric substrate holding device arrangement 100, 200 and 300 according to any one of embodiments one to three as described above.

During step a), a piezoelectric substrate 120, in particular, a bulk piezoelectric wafer, is provided on the substrate holding device arrangement 100, 200, 300.

During step b), ions 140, e.g., hydrogen or noble gas ions, are implanted into the substrate 120. The ions 140 can be implanted such that a mechanically weakened layer 142 is formed inside the substrate 120.

During implantation, an evacuation of charges 180 takes place from the substrate 120 being implanted to the substrate holding device 110 via the means for electrically connecting 160, 260 or 360. The evacuation of charges from the implanted piezoelectric substrate 120 is thus improved compared to a state of the art implantation process where the evacuation of charges 190 would only take place via the fixed restraint 130 of the substrate holding device 110.

The ion implanted piezoelectric substrate 120 can be used as a donor substrate in a subsequent layer transfer process to transfer a thin layer of the piezoelectric material onto a handle substrate to thereby form a piezo on insulator substrate.

In such a process, the ion implanted piezoelectric substrate 120 is attached e.g., by bonding, to a handle substrate, e.g., a silicon wafer with or without additional layers on the surface at which bonding takes place. The transfer of the piezoelectric layer then occurs at the mechanically weakened layer inside the piezoelectric substrate 120 by applying a thermal or mechanical load.

A number of embodiments of the present disclosure have been described. Nevertheless, it should be understood that various modifications and enhancements may be realized, e.g., by combining one or more features of the various embodiments.

1. A holding device arrangement for use in an implantation process of a piezoelectric substrate, comprising: a substrate holding device with an elastic and thermo-conductive layer for receiving a
piezoelectric substrate; and means for electrically connecting the surface of the elastic and thermo-conductive
layer for receiving the piezoelectric substrate to ground potential.

2. The holding device arrangement of claim 1, wherein the elastic and thermo-conductive layer comprises a polymer layer.

3. The holding device arrangement of claim 2, wherein the means for electrically connecting comprises at least one electrically conductive element) embedded in the elastic and thermo-conductive layer to render the elastic and thermo-conductive layer electrically conductive.

4. The holding device arrangement of claim 3, wherein the at least one electrically conductive element is at least one of metallic nano particles or metallic micro particles, carbon-based inclusions, graphite nanoparticles or carbon nanotubes.

5. The holding device arrangement of claim 2, wherein the means for electrically connecting comprises at least one metallic pin extending through the elastic and thermo-conductive layer to the substrate holding device.

6. The holding device arrangement of claim 5, wherein each one of the at least one metallic pin rests on a spring element provided in the substrate holding device.

7. The holding device arrangement of claim 6, wherein, in the absence of a substrate, the metallic pins protrude at least partially beyond the surface of the elastic and thermo-conductive layer.

8. The holding device arrangement of claim 2, wherein the means for electrically connecting comprises a conductive layer provided over the elastic and thermo-conductive layer and extending laterally at least partially over the side surface of the elastic and thermo-conductive layer to be in direct contact with the surface of the substrate holding device.

9. A method of implantation of a piezoelectric substrate, comprising:
providing a piezoelectric substrate on a holding device arrangement to thereby electrically connect the piezoelectric substrate to ground potential, the holding device arrangement comprising a substrate holding device with an elastic and thermo-conductive layer for receiving the piezoelectric substrate, and means for electrically connecting the surface of the elastic and thermo-conductive layer for receiving the piezoelectric substrate to ground potential; and
implanting atomic species into the piezoelectric substrate.

10. An ion implanter comprising a holding device arrangement according to claim 1.

11. The holding device arrangement of claim 2, wherein the polymer layer comprises an elastomer layer.

12. The holding device arrangement of claim 8, wherein the conductive layer comprises a metallic layer.

13. The holding device arrangement of claim 1, wherein the means for electrically connecting comprises at least one electrically conductive element embedded in the elastic and thermo-conductive layer to render the elastic and thermo-conductive layer electrically conductive.

14. The holding device arrangement of claim 13, wherein the at least one electrically conductive element is at least one of metallic nano particles or metallic micro particles, carbon-based inclusions, graphite nanoparticles or carbon nanotubes.

15. The holding device arrangement of claim 1, wherein the means for electrically connecting comprises at least one metallic pin extending through the elastic and thermo-conductive layer to the substrate holding device.

16. The holding device arrangement of claim 15, wherein each one of the at least one metallic pin rests on a spring element provided in the substrate holding device.

17. The holding device arrangement of claim 16, wherein, in the absence of a substrate, the metallic pins protrude at least partially beyond the surface of the elastic and thermo-conductive layer.

18. The holding device arrangement of claim 1, wherein the means for electrically connecting comprises a conductive layer provided over the elastic and thermo-conductive layer and extending laterally at least partially over the side surface of the elastic and thermo-conductive layer to be in direct contact with the surface of the substrate holding device.

19. The holding device arrangement of claim 18, wherein the conductive layer comprises a metallic layer.
